(19) United States
(12) Patent Application Publication
(10) Pub. No.: US 2025/0079352 A1
(43) Pub. Date: Mar. 6, 2025

(54) SEMICONDUCTOR DEVICE, HIGH FREQUENCY DEVICE, AND METHOD OF MANUFACTURING THE SAME

(71) Applicant: SUMITOMO ELECTRIC DEVICE INNOVATIONS, INC., Yokohama-shi (JP)

(72) Inventor: Takuma MORI, Yokohama-shi (JP)

(73) Assignee: SUMITOMO ELECTRIC DEVICE INNOVATIONS, INC., Yokohama-shi (JP)

(21) Appl. No.: 18/791,962

(22) Filed: Aug. 1, 2024

(30) Foreign Application Priority Data
Aug. 28, 2023 (JP) 2023-138188

(51) Int. Cl. H01L 23/66; H01L 23/00; H01L 23/31; H01L 23/495; H01L 25/00; H01L 25/16

(52) U.S. Cl. CPC H01L 23/66; H01L 23/3135; H01L 23/49562; H01L 24/48; H01L 25/16; H01L 25/50; H01L 24/32; H01L 24/73; H01L 2223/6611; H01L 2223/6655; H01L 2224/32245; H01L 2224/4814; H01L 2224/48245; H01L 2224/48265; H01L 2224/73265; H01L 2924/13064; H01L 2924/19041

(57) ABSTRACT

A semiconductor device includes a conductive base, a first chip and a second chip that are mounted on the base, and a first bonding wire that electrically connects the first chip to the second chip and transmits a high frequency signal. The base has a first opening extending through the base in a thickness direction of the base and overlapping at least a part of the first bonding wire with no conductor layer interposed between the first opening and the at least a part of the first bonding wire as viewed in the thickness direction of the base.

### CROSS REFERENCE TO RELATED APPLICATIONS

This application claims priority based on Japanese Patent Application No. 2023-138188 filed on Aug. 28, 2023, and the entire contents of the Japanese patent application are incorporated herein by reference.

### TECHNICAL FIELD

The present disclosure relates to a semiconductor device, a high frequency device, and a method of manufacturing the same.

### BACKGROUND

It is known that a plurality of chips including a semiconductor chip is mounted on a conductive base and the plurality of chips are electrically connected by using a bonding wire (for example, Patent literatures 1 to 3).
Patent literature 1: Japanese Unexamined Patent Application Publication No. 2018-113284
Patent literature 2: Japanese Unexamined Patent Application Publication No. 2003-318329
Patent literature 3: Japanese Unexamined Patent Application Publication No. 2012-104792

### SUMMARY

A semiconductor device according to an embodiment of the present disclosure includes a conductive base, a first chip and a second chip that are mounted on the base, and a first bonding wire that electrically connects the first chip to the second chip and transmits a high frequency signal. The base has a first opening extending through the base in a thickness direction of the base and overlapping at least a part of the first bonding wire with no conductor layer interposed between the first opening and the at least a part of the first bonding wire as viewed in the thickness direction of the base.

### BRIEF DESCRIPTION OF THE DRAWINGS

FIG. 1 is a plan view of a semiconductor device according to a first embodiment.

FIG. 2 is a cross-sectional view taken along line A-A of FIG. 1.

FIG. 3 is a circuit diagram of one set in the semiconductor device according to the first embodiment.

FIG. 4 is a plan view of the high frequency device according to the first embodiment.

FIG. 5 is a cross-sectional view taken along line A-A of FIG. 4.

FIG. 6 is a cross-sectional view of a high frequency device according to a comparative example.

FIG. 7 is a cross-sectional view illustrating a first example of the high frequency device according to the first embodiment.

FIG. 8 is a cross-sectional view illustrating a second example of a high frequency device according to the first embodiment.

FIG. 9 is a flowchart illustrating a method of manufacturing the high frequency device according to the first embodiment.

FIG. 10 is a plan view of a semiconductor device according to a second embodiment.

FIG. 11 is a circuit diagram of one set in the semiconductor device according to the second embodiment.

FIG. 12 is a plan view of a semiconductor device according to a third embodiment.

FIG. 13 is a cross-sectional view of a high frequency device according to the third embodiment.

FIG. 14 is a circuit diagram of one set in the semiconductor device according to the third embodiment.

### DETAILED DESCRIPTION

Characteristic may vary due to the difference in the height and length of bonding wires that electrically connect chips. In this case, it is difficult to adjust the characteristic.

The present disclosure has been made in view of the above problems, and an object of the present disclosure is to enable adjustment of characteristic.

### DESCRIPTION OF EMBODIMENTS OF PRESENT DISCLOSURE

First, the contents of embodiments of the present disclosure will be listed and explained.

(1) A semiconductor device according to an embodiment of the present disclosure includes a conductive base, a first chip and a second chip that are mounted on the base, and a first bonding wire that electrically connects the first chip to the second chip and transmits a high frequency signal. The base has a first opening extending through the base in a thickness direction of the base and overlapping at least a part of the first bonding wire with no conductor layer interposed between the first opening and the at least a part of the first bonding wire as viewed in the thickness direction of the base. Thus, it is possible to adjust the characteristic of the first bonding wire and to adjust the characteristic of the semiconductor device.

(2) In (1), the semiconductor device may further include a first terminal disposed outside the base, a second terminal disposed outside the base, a second bonding wire that electrically connects the first terminal to the first chip, and a third bonding wire that electrically connects the second terminal to the second chip. Thus, it is possible to adjust the characteristic of the first bonding wire disposed between the first terminal and the second terminal.

(3) In (2), the first chip may be a semiconductor chip having a transistor that amplifies a high frequency signal input to the first terminal or the second terminal and outputs the amplified high frequency signal to the second terminal or the first terminal. Thus, it is possible to adjust the characteristic of an inductor connected to the transistor.

(4) In (3), the second chip may include a dielectric substrate and an electrode disposed on the dielectric substrate, a capacitor is disposed between the electrode and the base, and the first bonding wire and the third bonding wire are connected to the electrode. Thus, it is possible to adjust the characteristic of an inductor connected to the semiconductor chip in a T-shaped circuit of an LCL filter.

(5) In (4), the second chip, the first bonding wire, and the third bonding wire may form a matching circuit that matches an impedance seen from the second terminal toward the third bonding wire and an impedance seen from the first bonding wire toward the semiconductor chip. Thus, it is possible to adjust the characteristic of the matching circuit of the transistor.

(6) In (1), the semiconductor device may further include a third chip mounted on the base, a first terminal disposed outside the base, a second terminal disposed outside the base, a second bonding wire that electrically connects the first terminal to the first chip, a third bonding wire that electrically connects the second chip to the third chip, and a fourth bonding wire that electrically connects the second terminal to the third chip. The base may have a second opening extending through the base in the thickness direction of the base and overlapping at least a part of the third bonding wire with no conductor layer interposed between the second opening and the at least a part of the third bonding wire as viewed in the thickness direction of the base. Thus, it is possible to adjust independently the characteristics of both the first and third bonding wires.

(7) In (6), the first chip may be a semiconductor chip having a transistor that amplifies a high frequency signal input to the first terminal or the second terminal and outputs the amplified high frequency signal to the second terminal or the first terminal. The second chip may include a first dielectric substrate and a first electrode disposed on the first dielectric substrate, a first capacitor may be disposed between the first electrode and the base, and the first bonding wire and the third bonding wire may be connected to the first electrode. The third chip may include a second dielectric substrate and a second electrode disposed on the second dielectric substrate, a second capacitor may be disposed between the second electrode and the base, and the third bonding wire and the fourth bonding wire may be connected to the second electrode. Thus, it is possible to adjust independently the characteristics of both the first and third bonding wires.

(8) In any one of (1) to (7), a resin layer may further include a resin layer disposed on the base and sealing the first chip, the second chip, and the first bonding wire. Thus, it is possible to adjust the characteristic of the shape of the first bonding wire, which cannot be finely adjusted.

(9) A high frequency device according to an embodiment of the present disclosure includes the semiconductor device according to any one of (1) to (8) and a mounting substrate. The mounting substrate includes an insulated substrate and a first conductor layer disposed on the insulated substrate, having the semiconductor device mounted thereon, and having a third opening, at least a part of the third opening overlapping at least a part of the first opening with no conductor layer interposed between the at least a part of the third opening and the at least a part of the first opening as viewed in a thickness direction of the insulated substrate. Thus, it is possible to adjust the characteristic of the first bonding wire.

(10) In (9), the insulated substrate may further include a second conductor layer disposed on a surface of the insulated substrate opposite to the first conductor layer with respect to the insulated substrate, the second conductor layer overlapping the third opening with no conductor layer interposed between the second conductor layer and the third opening as viewed in the thickness direction of the insulated substrate. Thus, it is possible to adjust the characteristic of the first bonding wire.

(11) In (9), the insulated substrate may further include a third conductor layer disposed in the insulated substrate and overlapping the third opening with no conductor layer interposed between the third conductor layer and the third opening as viewed in the thickness direction of the insulated substrate. Thus, it is possible to adjust the characteristic of the first bonding wire.

(12) A method of manufacturing a high frequency device according to an embodiment of the present disclosure includes preparing the semiconductor device according to any one of (1) to (8); preparing a plurality of mounting substrates in which respective reference potential surfaces have heights different from each other, at least a part of each of the reference potential surfaces overlapping at least a part of the first opening as viewed in a thickness direction of a corresponding mounting substrate of the plurality of mounting substrates when the semiconductor device is mounted on an upper surface of the mounting substrate; acquiring information on a high frequency characteristic of the semiconductor device; selecting, based on the acquired information, one mounting substrate from among the plurality of mounting substrates; and mounting the semiconductor device on the selected one mounting substrate. Thus, it is possible to adjust the characteristic of the high frequency device.

### DETAILS OF EMBODIMENTS OF PRESENT DISCLOSURE

Specific examples of a semiconductor device, a high frequency device, and a method of manufacturing the same according to embodiments of the present disclosure will be described below with reference to the drawings. The present disclosure is not limited to these examples, but is defined by the scope of the claims, and is intended to include all modifications within the meaning and scope equivalent to the scope of the claims.

### First Embodiment

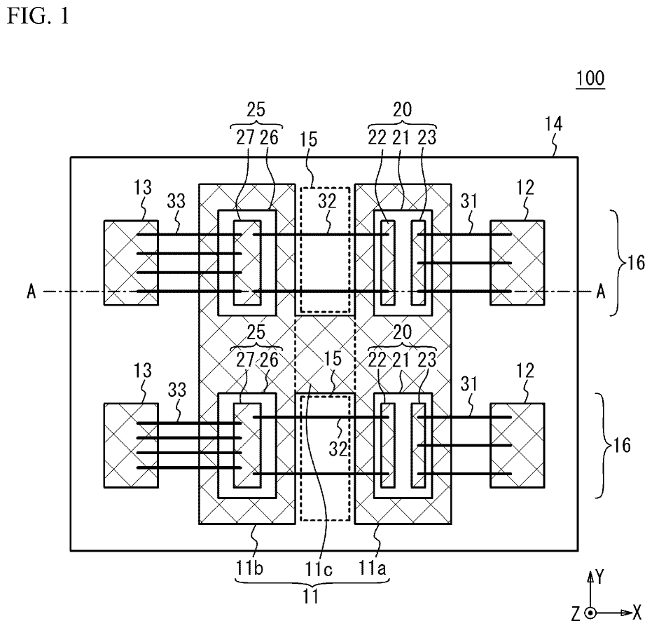

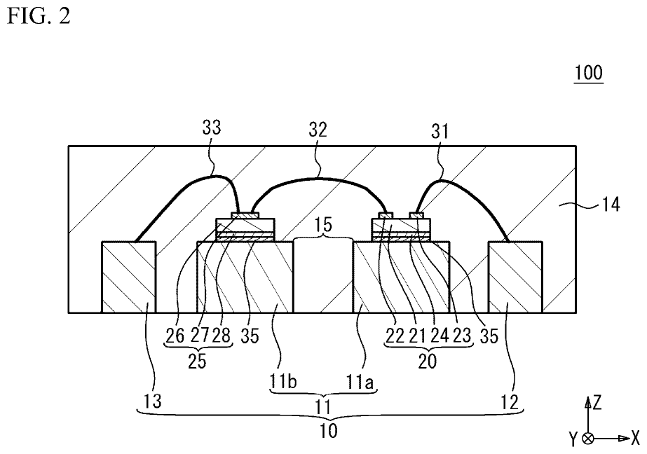

FIG. 1 is a plan view of a semiconductor device according to a first embodiment. FIG. 2 is a cross-sectional view taken along line A-A of FIG. 1. The thickness direction of a base 11 is defined as a Z direction, the extending direction of a straight line connecting terminals 13 and 12 is defined as an X direction, and the direction orthogonal to the X direction and the Z direction is defined as a Y direction.

As illustrated in FIGS. 1 and 2, a semiconductor device 100 of the first embodiment has a structure in which a semiconductor chip 20 and a passive element chip 25 that are mounted on base 11 of a conductive lead frame 10 are sealed with a resin layer 14. Lead frame 10 includes base 11, terminal 12, and terminal 13. Base 11, terminal 12 and terminal 13 are not in contact with each other. Base 11 is a die pad, and terminals 12 and 13 are leads. Connection bars connecting base 11, terminal 12, and terminal 13 before the cutting are not illustrated. The lower surfaces of base 11 and terminals 12 and 13 are exposed from the lower surface of resin layer 14.

Base 11 includes portions 11a to 11c and has an H-shaped planar shape. Portion 11a is closer to terminal 12 than portion 11b, and portion 11b is closer to terminal 13 than portion 11a. Terminal 12, semiconductor chip 20, passive element chip 25, and terminal 13 are arranged in order in the negative X-direction. Two sets 16 of terminal 12, semiconductor chip 20, passive element chip 25, and terminal 13 are disposed, and two sets 16 are arranged in the Y direction. The number of sets 16 may be one or three or more.

Semiconductor chip 20 is mounted on portion 11a, and passive element chip 25 is mounted on portion 11b. Semiconductor chip 20 includes a substrate 21 and electrodes 22 to 24. Substrate 21 is, for example, a semiconductor substrate. Electrodes 22 and 23 are disposed on the upper surface of substrate 21. Electrode 24 is disposed on the lower surface of substrate 21.

Passive element chip 25 includes a substrate 26 and electrodes 27 and 28. Substrate 26 is, for example, a dielectric substrate. Electrode 27 is disposed on the upper surface of substrate 26, and electrode 28 is disposed on the lower surface of substrate 26. A bonding layer 35 having conductivity is bonded to base 11 and electrodes 24 and 28. Electrodes 24 and 28 are electrically connected to base 11 and short-circuited. Bonding wires 31 electrically connect terminal 12 and electrode 23. Bonding wires 32 electrically connect electrode 22 and electrode 27. Bonding wires 33 electrically connect electrode 27 and terminal 13.

Openings 15 of base 11 are formed between portions 11a and 11b of base 11, and resin layer 14 is disposed in openings 15 between portions 11a and 11b of base 11. As viewed from the Z direction, a part of bonding wire 32 overlaps opening 15. No conductor layer is interposed between bonding wire 32 and opening 15.

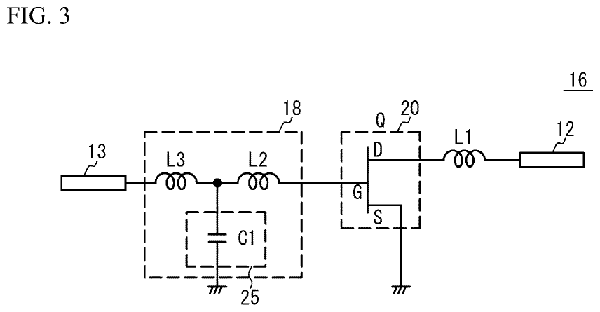

FIG. 3 is a circuit diagram of one set in the semiconductor device according to the first embodiment. As illustrated in FIG. 3, set 16 includes terminals 12 and 13, a transistor Q, inductors L1 to L3, and a capacitor C1. Transistor Q is, for example, a field effect transistor (FET), and has a source S, a gate G, and a drain D. Inductors L3 and L2 are connected in series between terminal 13 and gate G. Capacitor C1 is shunt-connected to a node between inductors L3 and L2. Source S is grounded. Inductor L1 is connected between drain D and terminal 12. Inductors L3 and L2 and capacitor C1 are T-shaped circuits of the LCL and form a matching circuit 18. Matching circuit 18 matches an impedance seen from terminal 13 toward matching circuit 18 and an impedance seen from matching circuit 18 toward transistor Q.

Transistor Q is disposed in semiconductor chip 20. Source S, gate G and drain D correspond to electrodes 24, 22 and 23, respectively. Electrode 22 is an input electrode to which a high frequency signal is input, and electrode 23 is an output electrode from which a high frequency signal is output. Capacitor C1 is disposed on passive element chip 25 and corresponds to substrate 26 and electrodes 27 and 28 interposing substrate 26. Inductors L1, L2, and L3 correspond to bonding wires 31, 32, and 33, respectively.

The high frequency signal input to terminal 13 passes through matching circuit 18 and is input to gate G. The high frequency signal amplified by transistor Q is output from drain D to terminal 12 through inductor L1. Inductor L1 may form part of a matching circuit. When semiconductor device 100 is used in an amplifier circuit for a base station of mobile communication, the frequencies of the high frequency signals are, for example, from 0.5 GHz to 10 GHz. The frequencies of the high frequency signals may be 10 GHz or higher.

Transistor Q is, for example, a GaN HEMT (Gallium Nitride High Electron Mobility Transistor) or an LDMOS (Laterally Diffused Metal Oxide Semiconductor). When transistor Q is the GaN HEMT, substrate 21 is, for example, a silicon carbide substrate or a gallium nitride substrate. Electrodes 22 to 24 are metal layers such as gold layers.

When passive element chip 25 includes capacitor C1, substrate 26 is, for example, a dielectric substrate, and is an alumina (aluminum oxide) substrate, a high-dielectric ceramic substrate having a relative permittivity larger than that of the alumina substrate, a silicon substrate, or a gallium arsenide substrate as an example. Electrodes 27 and 28 are metal layers such as gold layers.

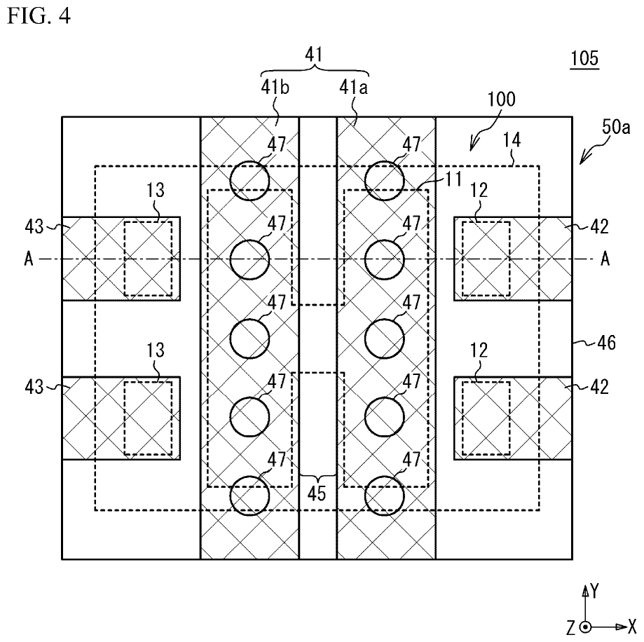

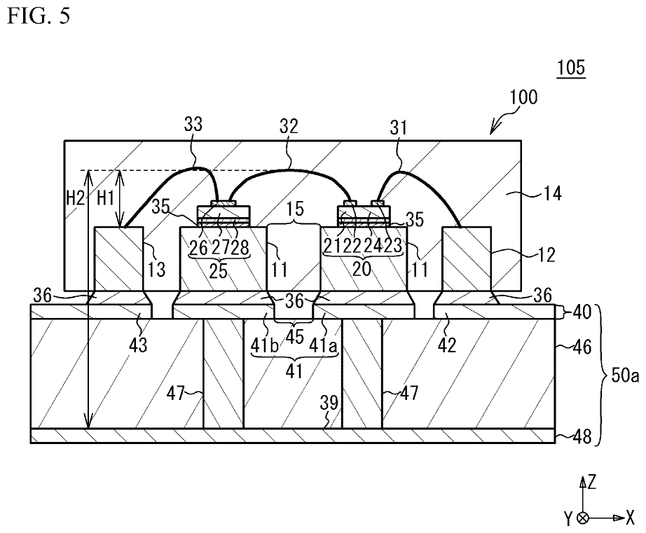

FIG. 4 is a plan view of the high frequency device according to the first embodiment. FIG. 5 is a cross-sectional view taken along line A-A of FIG. 4. In a high frequency device 105 of the first embodiment, semiconductor device 100 is mounted on a mounting substrate 50a. Mounting substrate 50a includes an insulated substrate 46, conductor layers 40 and 48, and vias 47. Conductor layer 40 is disposed on the upper surface of insulated substrate 46, and conductor layer 48 is disposed on the lower surface of insulated substrate 46. Conductor layer 40 includes a ground layer 41 and signal lines 42 and 43. Ground layer 41 includes ground layers 41a and 41b, and conductor layer 40 is not disposed between ground layers 41a and 41b, and a region between ground layers 41a and 41b is an opening 45. Conductor layer 48 and ground layers 41a and 41b are electrically connected and short-circuited by vias 47.

Base 11 of semiconductor device 100 is electrically connected to ground layer 41 by using a bonding layer 36, and is short-circuited. As viewed from the Z direction, at least a part of opening 15 of base 11 overlaps at least a part of opening 45 of ground layer 41. Terminals 12 and 13 of semiconductor device 100 are electrically connected to signal lines 42 and 43, respectively, by using bonding layer 36, and are short-circuited. A reference potential such as a ground potential supplied to conductor layer 48 is supplied to base 11 through vias 47, ground layer 41, and bonding layer 36. Thus, conductor layer 48 and base 11 have the same potential. The high frequency signal is input from signal line 43 to terminal 13 through bonding layer 36. The high frequency signal is output from terminal 12 to signal line 42 through bonding layer 36. Insulated substrate 46 is an organic insulator substrate such as a glass epoxy resin substrate. Conductor layers 40 and 48 and vias 47 are metal layers such as copper layers.

### COMPARATIVE EXAMPLE

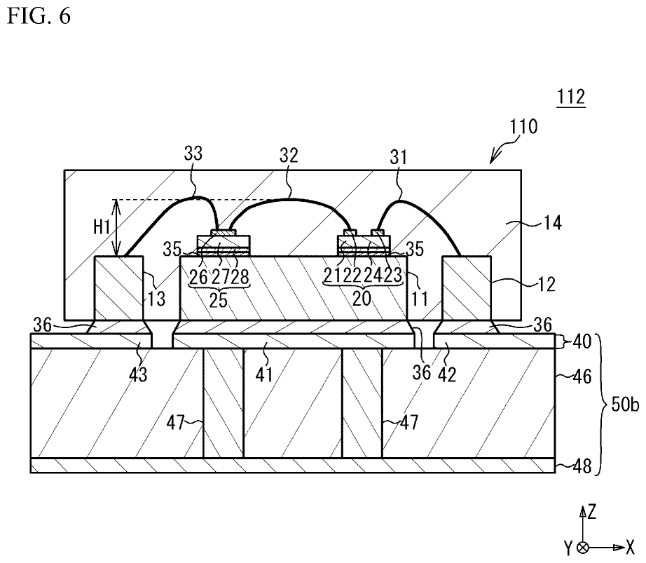

FIG. 6 is a cross-sectional view of a high frequency device according to a comparative example. In a high frequency device 112 of the comparative example, opening 15 is not disposed in base 11 of a semiconductor device 110. Opening 45 is not disposed in ground layer 41 of a mounting substrate 50b. When a height H1 of bonding wire 32 from base 11 and the length of bonding wire 32 are changed, the high frequency characteristic (for example, impedance) of bonding wire 32 is changed. Thus, the high frequency characteristic of matching circuit 18 is changed, and then the high frequency characteristic of semiconductor device 110 is changed.

When the high frequency characteristics of bonding wires 31 and 33 are changed, the high frequency characteristic of high frequency device 112 can be adjusted in mounting substrate 50b outside semiconductor device 110. However, when the high frequency characteristic of bonding wire 32 is changed, it is difficult to adjust the high frequency characteristic in mounting substrate 50b.

### Description of First Embodiment

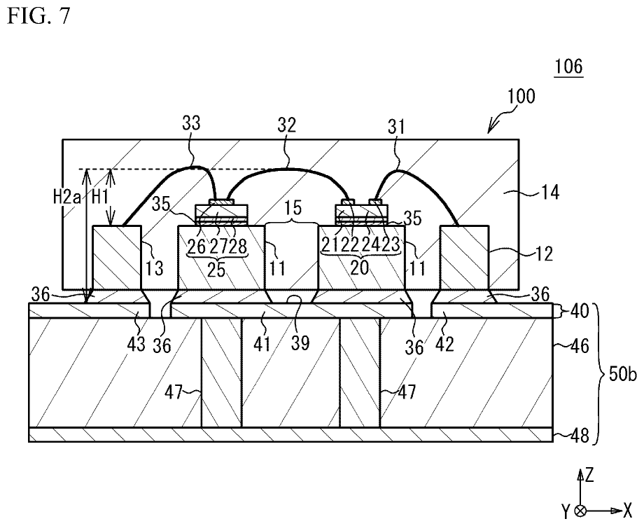

FIG. 7 is a cross-sectional view of a first example of the high frequency device according to the first embodiment. As illustrated in FIG. 7, in a high frequency device 106 of the first embodiment, mounting substrate 50b is used, and opening 45 is not disposed in ground layer 41. Other configurations are the same as those of FIG. 5, and the description thereof is omitted.

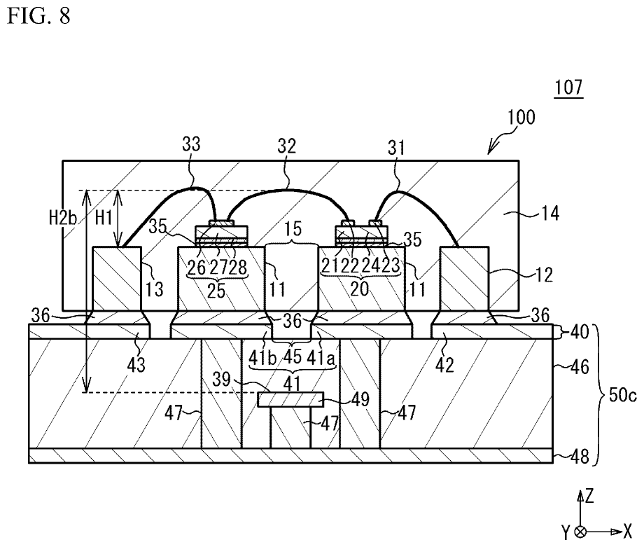

FIG. 8 is a cross-sectional view of a second example of the high frequency device according to the first embodiment. As illustrated in FIG. 8, in a high frequency device 107 of the first embodiment, a mounting substrate 50c is used, and opening 45 is disposed in ground layer 41. A conductor layer 49 inside mounting substrate 50c is disposed under opening 45. Conductor layer 49 is electrically connected to conductor layer 48 by via 47 and is short-circuited.

As illustrated in FIG. 5, in high frequency device 105, conductor layer 48 under bonding wire 32 serves as a reference potential surface 39. A distance H2 indicates a distance between bonding wire 32 and reference potential surface 39.

As illustrated in FIG. 7, in high frequency device 106, ground layer 41 under bonding wire 32 serves as reference potential surface 39. A distance H2a indicates a distance between bonding wire 32 and reference potential surface 39.

As illustrated in FIG. 8, in high frequency device 107, conductor layer 49 under bonding wire 32 serves as reference potential surface 39. A distance H2b indicates a distance between bonding wire 32 and reference potential surface 39.

Height H1 is, for example, 100 μm to 300 μm, the thickness of base 11 is, for example, 100 μm to 300 μm, and the thicknesses of mounting substrates 50a to 50c are, for example, 200 μm to 1,000 μm. Thus, distances H2, H2a, and H2b can be changed in a range of, for example, about 200 μm to 2,000 μm.

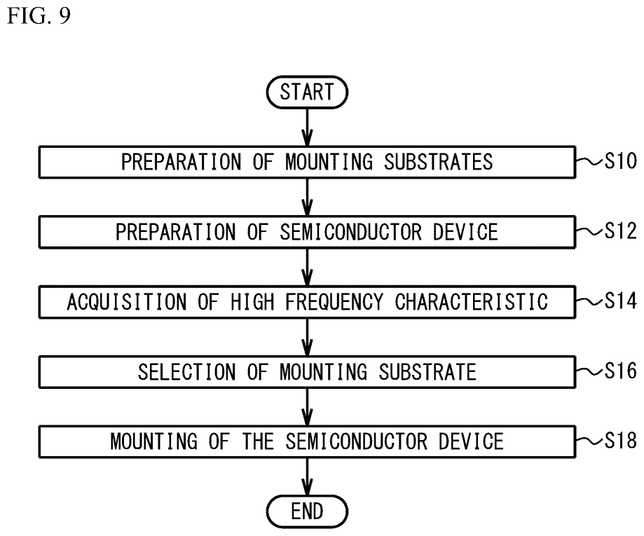

FIG. 9 is a flowchart illustrating a method of manufacturing a high frequency device according to the first embodiment. As illustrated in FIG. 9, the plurality of mounting substrates 50a to 50c having heights from the upper surfaces of mounting substrates 50a to 50c to respective reference potential surfaces 39 different from each other is prepared (step S10). Next, semiconductor device 100 of the first embodiment is prepared (step S12).

Next, information on the high frequency characteristic of semiconductor device 100 is acquired (step S14). The information on the high frequency characteristic can be acquired by measuring the high frequency characteristic of semiconductor device 100, for example. The high frequency characteristic can be measured by measuring, for example, a small signal characteristic such as an S parameter between terminals 13 and 12, and a large signal characteristic such as output power with respect to input power when a large signal having a large amplitude is input to semiconductor device 100. The information on the high frequency characteristic may be, for example, information on the shape of bonding wire 32.

Next, one mounting substrate is selected from the plurality of mounting substrates 50a to 50c based on the measurement result of step S14 (step S16). For example, mounting substrate 50a, 50b, or 50c is selected so that the high frequency characteristic when semiconductor device 100 is mounted on mounting substrate 50a, 50b, or 50c becomes a desired characteristic. Next, semiconductor device 100 is mounted on the selected mounting substrate 50a, 50b, or 50c (step S18). High frequency device 105, 106, or 107 is manufactured as described above.

As described above, in the first embodiment, distances H2, H2a, and H2b between bonding wire 32 and reference potential surface 39 can be changed by changing mounting substrates 50a to 50c. When distances H2, H2a, and H2b are changed, the capacitance between bonding wire 32 and reference potential surface 39 is changed. Thus, the high frequency characteristic of bonding wire 32 is changed. Even when the characteristic of semiconductor device 100 is different from a desired value because height H1 or the width of bonding wire 32 is different from the desired value and the high frequency characteristic of bonding wire 32 is different from the desired value, the high frequency characteristic of bonding wire 32 can be made closer to the desired value. Thus, the high frequency characteristic of the high frequency device can be made closer to the desired value.

### Second Embodiment

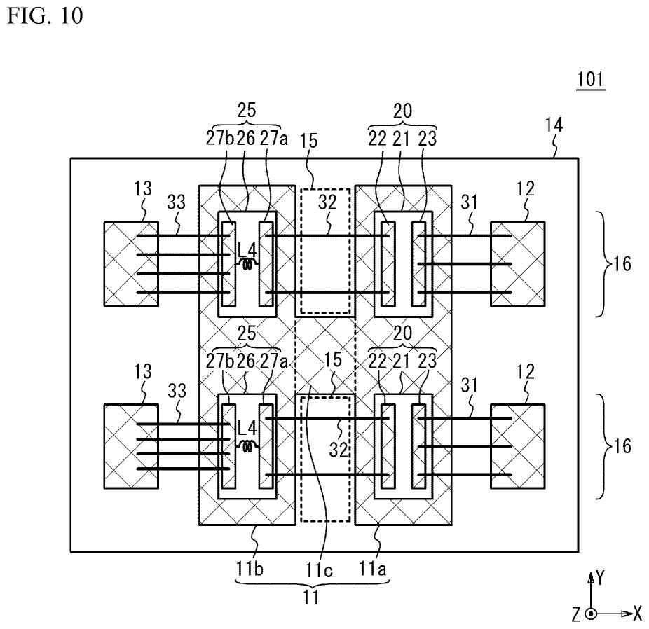

FIG. 10 is a plan view of a semiconductor device according to the second embodiment. As illustrated in FIG. 10, in a semiconductor device 101 of the second embodiment, electrodes 27a and 27b are disposed on the upper surface of passive element chip 25.

An inductor L4 is connected between electrodes 27a and 27b. Inductor L4 is, for example, a spiral inductor, but is illustrated using an inductor symbol in FIG. 10. Bonding wire 32 electrically connects electrode 22 and electrode 27a. Bonding wire 33 electrically connects electrode 27b and terminal 13. Other configurations are the same as those of FIG. 1, and the description thereof is omitted.

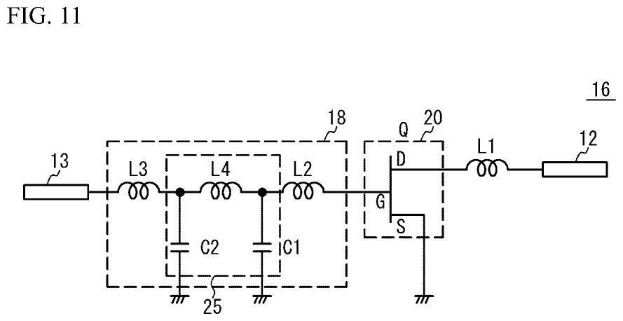

FIG. 11 is a circuit diagram of one set in the semiconductor device according to the second embodiment. As illustrated in FIG. 11, inductor L4 is connected in series between inductors L2 and L3. Capacitor C1 is shunt-connected between inductors L2 and L4. A capacitor C2 is shunt-connected between inductors L4 and L3. Inductors L2 to L4 and capacitors C1 and C2 form matching circuit 18. Inductor L4 and capacitors C1 and C2 are disposed in passive element chip 25. Inductor L4 is a spiral inductor formed on substrate 26. Capacitor C1 corresponds to substrate 26 and electrodes 27a and 28 interposing substrate 26. Capacitor C2 corresponds to substrate 26 and electrodes 27b and 28 interposing substrate 26. The other configurations are the same as those of FIG. 3, and the description thereof is omitted.

### [Simulation]

The resonance frequency of matching circuit 18 was simulated for a circuit A without openings 15 and 45 and a circuit B with opening 15 and a conductor layer overlapping opening 15 not disposed on mounting substrate 50a. The simulation conditions are as follows. L1: 0.5 nH, L2: 0.5 nH, L3: 1 nH, L4: 0.5 nH C1: 2 pF, C2: 4 pF Q: GaN-HEMT and Saturation power is 15 W, H1: 400 μm, H2: 1400 μm

Two resonance frequencies of a reflection characteristic S11 from terminal 13 to matching circuit 18 are formed. The two resonant frequencies are: Circuit A: 3.64 GHz, 7.82 GHz, Circuit B: 3.36 GHz, 7.38 GHz. As described above, the high frequency characteristic of matching circuit 18 can be changed by changing the distance between bonding wire 32 and reference potential surface 39. Thus, it is understood that the high frequency characteristic of matching circuit 18 can be adjusted by selecting any of mounting substrates 50a to 50c.

### Third Embodiment

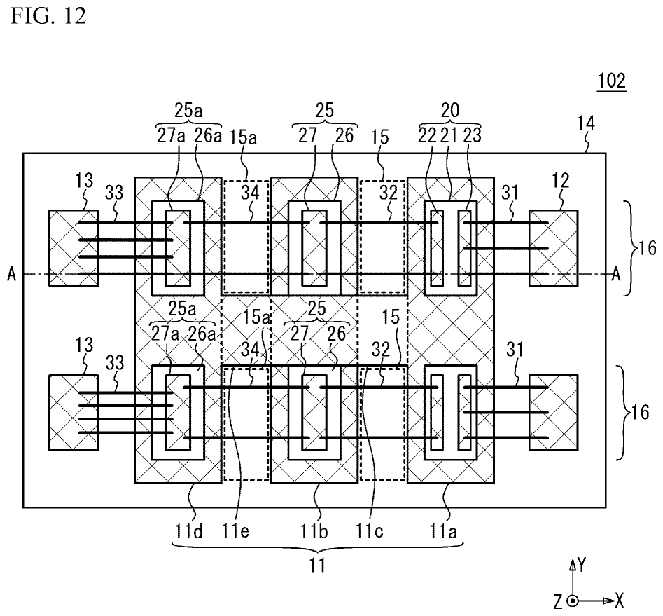

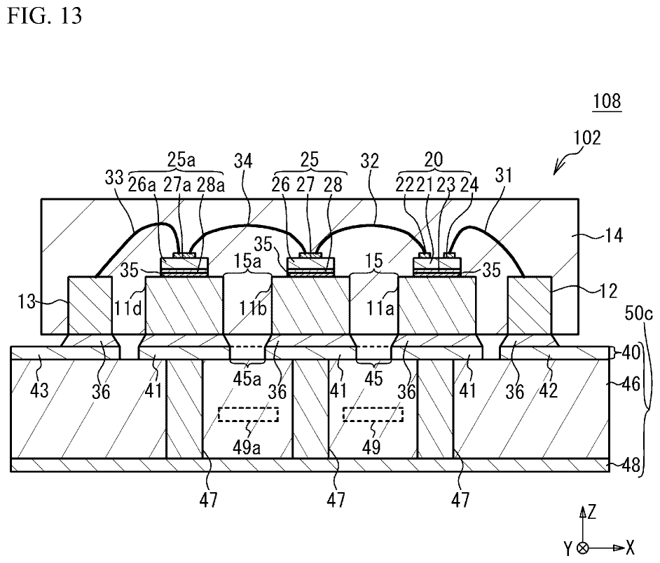

FIG. 12 is a plan view of a semiconductor device according to the third embodiment. FIG. 13 is a cross-sectional view of a high frequency device according to the third embodiment. In a high frequency device 108 of the third embodiment, a semiconductor device 102 is mounted on mounting substrate 50c. As illustrated in FIGS. 12 and 13, in semiconductor device 102 and high frequency device 108, base 11 includes portions 11d and 11e in addition to portions 11a to 11c. Portion 11d is closer to terminal 13 than portion 11b. Portion 11e connects portion 11b and portion 11d. An opening 15a is disposed between portions 11b and 11d. A passive element chip 25a is mounted on portion 11d. Passive element chip 25a includes a substrate 26a, electrode 27a, and an electrode 28a. A bonding wire 34 electrically connects electrode 27 and electrode 27a. Bonding wire 33 electrically connects electrode 27a and terminal 13.

In mounting substrate 50c, conductor layer 40 may be disposed or opening 45 may be disposed so as to overlap opening 15 as viewed from the Z direction. When opening 45 is disposed, conductor layer 49 may be disposed or may not be disposed. In mounting substrate 50c, conductor layer 40 may be disposed or an opening 45a may be disposed so as to overlap opening 15a as viewed from the Z direction. When opening 45a is disposed, a conductor layer 49a may be disposed or may not be disposed.

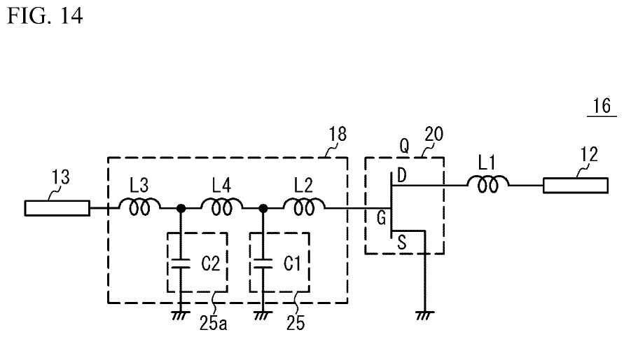

FIG. 14 is a circuit diagram of one set in the semiconductor device according to the third embodiment. As illustrated in FIG. 14, capacitor C1 is disposed on passive element chip 25, and capacitor C2 is disposed on passive element chip 25a. Inductor L4 corresponds to bonding wire 34. The other configurations are the same as those of FIG. 11, and the description thereof is omitted.

In the third embodiment, a plurality of mounting substrates 50c are prepared, which are different in both the height of the reference potential surface overlapping opening 15 and the height of the reference potential surface overlapping opening 15a as viewed from the Z direction. One mounting substrate 50c is selected from the plurality of mounting substrates 50c based on the information on the high frequency characteristic of semiconductor device 102. Thus, the high frequency characteristics of bonding wires 32 and 34 are independently adjusted, and the characteristic of matching circuit 18 can be adjusted more finely.

According to the first embodiment to the third embodiment, semiconductor chip 20 (first chip) and passive element chip 25 (second chip) are mounted on conductive base 11. Bonding wires 32 (first bonding wire) of the first embodiment to the third embodiment electrically connect semiconductor chip 20 and passive element chip 25, and transmit a high frequency signal. Base 11 has opening 15 (first opening) that extends through in the thickness direction and overlaps at least a part of bonding wire 32 as viewed in the thickness direction of base 11. No conductor layer is disposed between bonding wire 32 and opening 15. That is, bonding wire 32 overlaps opening 15 with no conductor layer interposed between bonding wire 32 and opening 15 as viewed in the Z direction.

As illustrated in step S14 of FIG. 9, information on the high frequency characteristic of the semiconductor device is acquired, and one mounting substrate on which the semiconductor device is mounted is selected as illustrated in step S16. The semiconductor device is mounted on one mounting substrate selected as in step S18. Thus, it is possible to adjust the high frequency characteristic of bonding wire 32 in the semiconductor device, and the characteristic of the semiconductor device can be adjusted.

Both the first chip and the second chip may be passive element chips. Opening 15 is described as an example in which the contour of base 11 viewed in the Z direction is a cutout. Portion 11c may not be disposed, and opening 15 may be disposed between portions 11a and 11b. Opening 15 may be a closed space surrounded by base 11. If portions 11a and 11b of base 11 are separated from each other and portion 11c is not disposed, parasitic inductance between the reference potential of semiconductor chip 20 and the reference potential of passive element chip 25 increases. Thus, portion 11c may connect portions 11a and 11b.

Terminal 12 (first terminal) is disposed outside base 11, and outputs a high frequency signal. Terminal 13 (second terminal) is disposed outside base 11, and the high frequency signal is input to terminal 13. Bonding wire 31 (second bonding wire) electrically connects terminal 12 and semiconductor chip 20. Bonding wire 33 (third bonding wire) electrically connects terminal 13 and passive element chip 25. Thus, it is possible to adjust the high frequency characteristic of bonding wire 32 disposed between terminal 13 to which the signal is input and terminal 12 from which the signal is output.

Semiconductor chip 20 includes transistor Q that amplifies the high frequency signal input to terminal 13 and outputs the amplified high frequency signal to terminal 12. Thus, the high frequency characteristic of the inductor connected to transistor Q for amplification can be adjusted.

Passive element chip 25 includes substrate 26 which is a dielectric and electrode 27 disposed on substrate 26, and capacitor C1 is formed between electrode 27 and base 11. Bonding wires 32 and 33 are connected to electrode 27. Thus, it is possible to adjust the high frequency characteristic of the inductor connected to semiconductor chip 20 in the T-shaped circuit of the LCL formed by passive element chip 25 and bonding wires 32 and 33.

Passive element chip 25 and bonding wires 32 and 33 form matching circuit 18 that matches an impedance seen from terminal 13 toward bonding wire 33 and an impedance seen from bonding wire 32 toward semiconductor chip 20. Thus, the high frequency characteristic of matching circuit 18 of transistor Q can be adjusted.

Resin layer 14 is disposed on base 11 and seals semiconductor chip 20, passive element chip 25, and bonding wires 31 to 33. In this case, since bonding wire 32 is disposed in resin layer 14, the shape of bonding wire 32 cannot be finely adjusted. However, the high frequency characteristic of bonding wire 32 can be adjusted by providing opening 15.

In mounting substrate 50b, conductor layer 40 (first conductor layer) is disposed on insulated substrate 46, semiconductor device 100 or 101 is mounted thereon, and conductor layer 40 overlaps opening 15 with no conductor layer interposed between conductor layer 40 and opening 15 as viewed from the Z direction.

In mounting substrates 50a and 50c, conductor layer 40 (first conductor layer) has opening 45 (third opening) in which at least a part of opening 45 overlapping at least a part of opening 15 with no conductor layer interposed between at least a part of opening 45 and at least a part of opening 15 as viewed from the Z direction.

In mounting substrate 50a, conductor layer 48 (second conductor layer) is disposed on the surface of insulated substrate 46 opposite to conductor layer 40, and overlaps opening 45 with no conductor layer interposed between conductor layer 48 and conductor layer 40 as viewed from the Z direction.

In mounting substrate 50c, conductor layer 49 (third conductor layer) is disposed inside insulated substrate 46, and overlaps opening 45 with no conductor layer interposed conductor layer 49 and opening 45 as viewed from the Z direction. A plurality of mounting substrates 50c having different heights of conductor layer 49 in the Z direction may be prepared.

In this way, the mounting substrates on which semiconductor devices 100 and 101 are mounted are selected from mounting substrates 50a and 50c. Thus, it is possible to adjust the high frequency characteristic of bonding wire 32.

A description is given of an example in which opening 45 is a portion between ground layers 41a and 41b which are separated from each other. Opening 45 may be a cutout of the contour of ground layer 41. Opening 45 may be a closed space surrounded by ground layer 41.

In the third embodiment, bonding wire 31 (second bonding wire) electrically connects terminal 12 and semiconductor chip 20. Bonding wire 32 (first bonding wire) electrically connects semiconductor chip 20 and passive element chip 25. Bonding wire 34 (third bonding wire) electrically connects passive element chip 25 and passive element chip 25a (third chip). Bonding wire 33 (fourth bonding wire) electrically connects passive element chip 25a and terminal 13. Base 11 includes opening 15 that overlaps at least a part of bonding wire 32 with no conductor layer interposed between opening 15 and at least a part of bonding wire 32 as viewed from the Z direction, and opening 15a (second opening) that overlaps at least a part of bonding wire 34 with no conductor layer interposed between opening 15a and at least a part of bonding wire 34. Thus, the high frequency characteristics of both bonding wires 32 and 34 can be independently adjusted.

Semiconductor chip 20 includes transistor Q that amplifies the high frequency signal input to terminal 13 and outputs the amplified high frequency signal to terminal 12. Passive element chip 25 includes substrate 26 (first dielectric substrate) and electrode 27 (first electrode) disposed on substrate 26, and capacitor C1 (first capacitor) is formed between electrode 27 and base 11. Passive element chip 25a includes substrate 26a (second dielectric substrate) and electrode 27a (second electrode) disposed on substrate 26a, and capacitor C2 (second capacitor) is formed between electrode 27a and base 11. Thus, the high frequency characteristics of both bonding wires 32 and 34, which correspond to inductors L2 and L4 in matching circuit 18, can be independently adjusted.

Although the example of the input matching circuit as matching circuit 18 has been described, a passive element chip may be disposed between semiconductor chip 20 and terminal 13, and opening 15 of base 11 may be disposed so as to overlap a bonding wire that electrically connects semiconductor chip 20 and the passive element chip. In this way, transistor Q may amplify the high frequency signal input to terminal 12 and output the amplified high frequency signal to terminal 13. Although bonding wire 32 is disposed in matching circuit 18 in the above description, bonding wire 32 for electrically connecting semiconductor chip 20 (first chip) and passive element chip 25 (second chip) may be any bonding wire that allows a high frequency signal to propagate.

The embodiments disclosed herein are to be considered in all respects as illustrative and not restrictive. The scope of the present disclosure is defined by the appended claims rather than the foregoing description, and is intended to include all modifications within the scope and meaning equivalent to the claims.

What is claimed is:

1. A semiconductor device comprising:
a conductive base;
a first chip and a second chip that are mounted on the base; and
a first bonding wire that electrically connects the first chip to the second chip and transmits a high frequency signal,
wherein the base has a first opening extending through the base in a thickness direction of the base and overlapping at least a part of the first bonding wire with no conductor layer interposed between the first opening and the at least a part of the first bonding wire as viewed in the thickness direction of the base.

2. The semiconductor device according to claim 1, further comprising:
a first terminal disposed outside the base;
a second terminal disposed outside the base;
a second bonding wire that electrically connects the first terminal to the first chip; and
a third bonding wire that electrically connects the second terminal to the second chip.

3. The semiconductor device according to claim 2, wherein
the first chip is a semiconductor chip having a transistor that amplifies a high frequency signal input to the first terminal or the second terminal and outputs the amplified high frequency signal to the second terminal or the first terminal.

4. The semiconductor device according to claim 3, wherein
the second chip includes a dielectric substrate and an electrode disposed on the dielectric substrate, a capacitor is disposed between the electrode and the base, and the first bonding wire and the third bonding wire are connected to the electrode.

5. The semiconductor device according to claim 4, wherein
the second chip, the first bonding wire, and the third bonding wire form a matching circuit that matches an impedance seen from the second terminal toward the third bonding wire and an impedance seen from the first bonding wire toward the semiconductor chip.

6. The semiconductor device according to claim 1, further comprising:
a third chip mounted on the base;
a first terminal disposed outside the base;
a second terminal disposed outside the base;
a second bonding wire that electrically connects the first terminal to the first chip;
a third bonding wire that electrically connects the second chip to the third chip; and
a fourth bonding wire that electrically connects the second terminal to the third chip, wherein
the base has a second opening extending through the base in the thickness direction of the base and overlapping at least a part of the third bonding wire with no conductor layer interposed between the second opening and the at least a part of the third bonding wire as viewed in the thickness direction of the base.

7. The semiconductor device according to claim 6, wherein
the first chip is a semiconductor chip having a transistor that amplifies a high frequency signal input to the first terminal or the second terminal and outputs the amplified high frequency signal to the second terminal or the first terminal,
the second chip includes a first dielectric substrate and a first electrode disposed on the first dielectric substrate, a first capacitor is disposed between the first electrode and the base, and the first bonding wire and the third bonding wire are connected to the first electrode, and
the third chip includes a second dielectric substrate and a second electrode disposed on the second dielectric substrate, a second capacitor is disposed between the second electrode and the base, and the third bonding wire and the fourth bonding wire are connected to the second electrode.

8. The semiconductor device according to claim 1, further comprising:
a resin layer disposed on the base and sealing the first chip, the second chip, and the first bonding wire.

9. A high frequency device comprising:
the semiconductor device according to claim 1; and
a mounting substrate including:
an insulated substrate; and
a first conductor layer disposed on the insulated substrate, having the semiconductor device mounted thereon, and having a third opening, at least a part of the third opening overlapping at least a part of the first opening with no conductor layer interposed between the at least a part of the third opening and the at least a part of the first opening as viewed in a thickness direction of the insulated substrate.

10. The high frequency device according to claim 9, further comprising:
a second conductor layer disposed on a surface of the insulated substrate opposite to the first conductor layer with respect to the insulated substrate, the second conductor layer overlapping the third opening with no conductor layer interposed between the second conductor layer and the third opening as viewed in the thickness direction of the insulated substrate.

11. The high frequency device according to claim 9, further comprising:
a third conductor layer disposed in the insulated substrate and overlapping the third opening with no conductor layer interposed between the third conductor layer and the third opening as viewed in the thickness direction of the insulated substrate.

12. A method of manufacturing a high frequency device, the method comprising:
preparing the semiconductor device according to claim 1;
preparing a plurality of mounting substrates in which respective reference potential surfaces have heights different from each other, at least a part of each of the reference potential surfaces overlapping at least a part of the first opening as viewed in a thickness direction of a corresponding mounting substrate of the plurality of mounting substrates when the semiconductor device is mounted on an upper surface of the mounting substrate;
acquiring information on a high frequency characteristic of the semiconductor device;
selecting, based on the acquired information, one mounting substrate from among the plurality of mounting substrates; and
mounting the semiconductor device on the selected one mounting substrate.
